(19) United States
(12) Patent Application Publication
(10) Pub. No.: US 2025/0258985 A1
(43) Pub. Date: Aug. 14, 2025

(54) Method and apparatus for evaluating circuit using artificial neural network model

(71) Applicant: ALSEMY INC., Seoul (KR)

(72) Inventors: Chanwoo PARK, Seongnam-si (KR); Hyunbo CHO, Seoul (KR)

(21) Appl. No.: 18/823,818

(22) Filed: Sep. 4, 2024

(30) Foreign Application Priority Data
Feb. 14, 2024 (KR) 10-2024-0020824
May 17, 2024 (KR) 10-2024-0064539

(51) Int. Cl. G06F 30/33

(52) U.S. Cl. CPC G06F 30/33

(57) ABSTRACT

A circuit evaluation method performed by a computing device according to an embodiment of the present disclosure. The method includes generating a target circuit graph including a plurality of nodes and edges based on target circuit data, generating a target circuit vector based on the generated target circuit graph, and generating circuit evaluation data based on the target circuit vector.

### TECHNICAL FIELD

The present disclosure relates to a circuit evaluation method and apparatus, and more specifically, to a circuit evaluation methods and apparatus for generating a vector including characteristics of a device and a circuit using a trained artificial neural network model and predicting performance of the circuit.

### BACKGROUND ART

Systems, such as integrated circuits, are becoming increasingly complex, and the time and cost of entering the verification process during system development are also increasing. For example, in the process of designing a circuit, it takes a lot of time to evaluate the circuit, and when tens of thousands or more tests are performed for system on chip (SOC) verification, a large amount of manpower and computing resources are needed to simulate the test. Accordingly, there is a need for a method that can reduce the time required for circuit verification and evaluation, computing resources, and manpower.

### SUMMARY

### Technical Problem

The present disclosure has been devised in accordance with the foregoing background, and an object of the present disclosure is to shorten a circuit evaluation time by using an artificial neural network model.

An object of the present disclosure is to quickly generate a vector by using measurement data in a process of compressing features of a device and a circuit, and improve a circuit evaluation speed and accuracy through the generated vector.

However, the problems to be solved in the present disclosure are not limited to the above-mentioned problems, and still other problems not mentioned may be clearly understood based on the following description.

### Technical Solution

A circuit evaluation method performed by a computing device including at least one processor according to an embodiment of the present disclosure for realizing the above-described problem may include generating a target circuit graph including a plurality of nodes and edges based on target circuit data, generating a target circuit vector based on the generated target circuit graph, and generating circuit evaluation data based on the target circuit vector.

Alternatively, the target circuit data comprises a device vector of a predetermined dimension generated on the basis of electrical characteristics or measurement data of the device.

Alternatively, the device vector is generated by a pre-trained first neural network model, and the first neural network model includes any one of a convolutional neural network (CNN), a recurrent neural network (RNN), an Generative Adversarial Network (GAN), and a transformer.

Alternatively, the device may comprise a transistor and the electrical characteristics or measurement data of the device may comprise drain-source voltage, gate-source voltage, bulk-source voltage, drain current or gate capacitance.

Alternatively, the generating the target circuit vector may generate the target circuit vector by using a second neural network model including a graph neural network (GNN), a graph convolutional network (GCN), or a graph attention network (GAT).

Alternatively, the circuit evaluation data includes a figure of merit (POM) corresponding to the target circuit data, and the figure of merit includes one or more of gain, power, bandwidth, or delay.

Alternatively, generating the circuit evaluation data further includes predicting a voltage or a current applied to the node based on the target circuit vector and a device vector corresponding to any one of the plurality of nodes.

A circuit evaluation device using an artificial neural network according to an embodiment of the present disclosure includes a circuit graph module that generates a target circuit vector based on target circuit data. The target circuit data includes one or more pieces of device information and connection relationship information between devices. The circuit graph module includes a graph generation unit that generates a target circuit graph including edges corresponding to connection relationship information between a plurality of nodes corresponding to the device information and devices, and a second neural network model trained to generate a target circuit vector based on the target circuit graph.

Alternatively, the circuit evaluation device includes a vector generation module that generates a device vector of a preset dimension generated based on electrical characteristics of the device or measurement data, and the target circuit data includes the device vector.

Alternatively, the vector generation module includes a trained first neural network model trained to generate the device vector based on electrical characteristics of the device or measurement data, and the first neural network model includes any one of a convolutional neural network (CNN), a recurrent neural network (RNN), a Generative Adversarial Network (GAN), or a transformer.

Alternatively, the first neural network model may be trained to generate the device vector based on a drain-source voltage, a gate-source voltage, bulk-source voltage, drain current, gate capacitance, I-V characteristic, or C-V characteristic.

Alternatively, the second neural network model may be any one of a Graph Neural Network (GNN), a Graph Convolution Network (GCN), or a Graph Attention Network (GAT).

Alternatively, the circuit evaluation device may include a circuit evaluation module configured to predict performance corresponding to the target circuit data, and the performance may be a figure of merit (POM) including one or more of gain, power, bandwidth, or delay.

Alternatively, the circuit evaluation module may include a third neural network model trained to predict the performance based on the target circuit vector.

Alternatively, the circuit evaluation device may include a circuit evaluation module that predicts a state of any one of the devices included in the target circuit data, and the circuit evaluation module may include a third neural network model trained to predict a voltage or a current applied to a device corresponding to the device vector based on the target circuit vector and the device vector.

According to an embodiment of the present disclosure, a computing device for evaluating a circuit based on a trained neural network model includes a processor including at least one core, a memory including program codes executable by the processor, and a network unit for obtaining data. The processor generates a target circuit graph based on target circuit data, generates a target circuit vector based on the generated target circuit graph, and generates circuit evaluation data based on the target circuit vector. The target circuit data may include one or more pieces of device information and connection relationship information between devices, and the target circuit graph may include a plurality of nodes corresponding to the device information and edges corresponding to the connection relationship information between the devices. The target circuit vector may be generated by using a neural network model of any one of a Graph Neural Network (GNN), a Graph Convolution Network (GCN), or a Graph Attention Network (GAT) as an input of the target circuit graph.

Alternatively, the node included in the target circuit graph may include a device vector of a preset dimension generated by using a neural network model based on electrical characteristics or measurement data of the device corresponding to the node.

### Advantageous Effects

The present disclosure can effectively utilize a pre-learned artificial neural network model in the field of circuit design to improve the accuracy and speed of circuit evaluation.

In the present disclosure, the I-V and C-V characteristics of a device such as a transistor or a diode are input, and a vector well representing the device is extracted and used for circuit evaluation.

The present disclosure analyzes a circuit converted into a graph through an artificial neural network model, and predicts individual node characteristics such as voltage and current of each node included in the circuit, and at the same time, can quickly predict the figure of merit of the entire circuit including gain, power, delay, and bandwidth.

### BRIEF DESCRIPTION OF DRAWINGS

FIG. 1 is a block diagram of a computing device according to an embodiment of the present disclosure.

FIG. 2 is a block diagram illustrating a circuit evaluation apparatus according to an embodiment of the present disclosure.

FIG. 3 is a diagram illustrating a first neural network model for generating a device vector according to an embodiment of the present disclosure.

FIG. 4 is a diagram illustrating a device vector corresponding to a device of a circuit to be evaluated.

FIG. 5 is a diagram illustrating a second neural network model for generating a vector representing a circuit characteristic according to an embodiment of the present disclosure.

FIG. 6 is a diagram illustrating a third neural network model for generating circuit evaluation data according to an embodiment of the present disclosure.

FIG. 7 is a flowchart illustrating a circuit evaluation method according to an embodiment of the present disclosure.

### DETAILED DESCRIPTION OF EXEMPLARY EMBODIMENTS

Embodiments of the present disclosure will be described in detail below with reference to the accompanying drawings so that those having ordinary skill in the art of the present disclosure (hereinafter referred to as those skilled in the art) can easily implement the present disclosure. The embodiments presented in the present disclosure are provided to enable those skilled in the art to use or practice the content of the present disclosure. Accordingly, various modifications to embodiments of the present disclosure will be apparent to those skilled in the art. That is, the present disclosure may be implemented in various different forms and is not limited to the following embodiments.

The same or similar reference numerals denote the same or similar components throughout the specification of the present disclosure. Additionally, in order to clearly describe the present disclosure, reference numerals for parts that are not related to the description of the present disclosure may be omitted in the drawings.

The term “or” used herein is intended not to mean an exclusive “or” but to mean an inclusive “or.” That is, unless otherwise specified herein or the meaning is not clear from the context, the clause “X uses A or B” should be understood to mean one of the natural inclusive substitutions. For example, unless otherwise specified herein or the meaning is not clear from the context, the clause “X uses A or B” may be interpreted as any one of a case where X uses A, a case where X uses B, and a case where X uses both A and B.

The term “and/or” used herein should be understood to refer to and include all possible combinations of one or more of listed related concepts.

The terms “include” and/or “including” used herein should be understood to mean that specific features and/or components are present. However, the terms “include” and/or “including” should be understood as not excluding the presence or addition of one or more other features, one or more other components, and/or combinations thereof.

Unless otherwise specified herein or unless the context clearly indicates a singular form, the singular form should generally be construed to include “one or more.”

The term “N-th (N is a natural number)” used herein can be understood as an expression used to distinguish the components of the present disclosure according to a predetermined criterion such as a functional perspective, a structural perspective, or the convenience of description. For example, in the present disclosure, components performing different functional roles may be distinguished as a first component or a second component. However, components that are substantially the same within the technical spirit of the present disclosure but should be distinguished for the convenience of description may also be distinguished as a first component or a second component.

The term “acquisition” used herein can be understood to mean not only receiving data over a wired/wireless communication network connecting with an external device or a system, but also generating data in an on-device form.

Meanwhile, the term “module” or “unit” used herein may be understood as a term referring to an independent functional unit processing computing resources, such as a computer-related entity, firmware, software or part thereof, hardware or part thereof, or a combination of software and hardware. In this case, the “module” or “unit” may be a unit composed of a single component, or may be a unit expressed as a combination or set of multiple components. For example, in the narrow sense, the term “module” or “unit” may refer to a hardware component or set of components of a computing device, an application program performing a specific function of software, a procedure implemented through the execution of software, a set of instructions for the execution of a program, or the like. Additionally, in the broad sense, the term “module” or “unit” may refer to a computing device itself constituting part of a system, an application running on the computing device, or the like. However, the above-described concepts are only examples, and the concept of “module” or “unit” may be defined in various manners within a range understandable to those skilled in the art based on the content of the present disclosure.

The term “model” used herein may be understood as a system implemented using mathematical concepts and language to solve a specific problem, a set of software units intended to solve a specific problem, or an abstract model for a process intended to solve a specific problem. For example, a neural network “model” may refer to an overall system implemented as a neural network that is provided with problem-solving capabilities through training. In this case, the neural network may be provided with problem-solving capabilities by optimizing parameters connecting nodes or neurons through training. The neural network “model” may include a single neural network, or a neural network sot in which multiple neural networks are combined together.

The term “inductive bias” used herein can be understood as a set of assumptions that enable the inductive inference of a deep learning model. In order to resolve the generalization error in which a deep learning model exhibits appropriate performance only for given training data, it is necessary for the deep learning model to infer an output close to an accurate output for data other than the given training data. Accordingly, “inductive bias” can be understood as a set of preconditions that a deep learning model has in the process of being trained to predict the output of an ungiven input.

The term “block” used herein may be understood as a set of components classified based on various criteria such as type, function, etc. Accordingly, the components classified as each “block” may be changed in various manners depending on the criteria. For example, a neural network “block” may be understood as a set of neural networks including one or more neural networks. In this case, it can be assumed that the neural networks included in the neural network “block” perform predetermined operations to achieve a common purpose that serves as a classification criterion.

The term “operation function” used herein can be understood as a mathematical presentation for a configurational unit that performs a specific function or processes an operation. For example, the “operation function” of a neural network block can be understood as a mathematical representation representative of a neural network block that processes a specific operation. Accordingly, the relationship between the input and output of the neural network block can be represented by a formula through the “operation function” of the neural network block.

The foregoing descriptions of the terms are intended to help to understand the present disclosure. Accordingly, it should be noted that unless the above-described terms are explicitly described as limiting the content of the present disclosure, the terms in the content of the present disclosure are not used in the sense of limiting the technical spirit of the present disclosure.

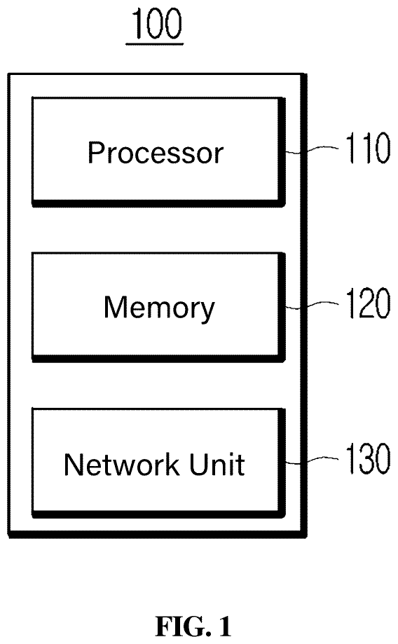

FIG. 1 is a block diagram of a computing device according to an embodiment of the present disclosure.

A computing device 100 according to an embodiment of the present disclosure may be a hardware device or part of a hardware device that performs the comprehensive processing and calculation of data, or may be a software-based computing environment that is connected to a communication network. For example, the computing device 100 may be a server that performs an intensive data processing function and shares resources, or may be a client that shares resources through interaction with a server. Furthermore, the computing device 100 may be a cloud system in which a plurality of servers and clients interact with each other and comprehensively process data. Since the above descriptions are only examples related to the type of computing device 100, the type of computing device 100 may be configured in various manners within a range understandable to those skilled in the art based on the content of the present disclosure.

Referring to FIG. 1, the computing device 100 according to an embodiment of the present disclosure may include a processor 110, memory 120, and a network unit 130. However, FIG. 1 shows only an example, and the computing device 100 may include other components for implementing a computing environment. Furthermore, only some of the components disclosed above may be included in the computing device 100.

The processor 110 according to an embodiment of the present disclosure may be understood as a configuration unit including hardware and/or software for performing computing operation. For example, the processor 110 may read a computer program and perform data processing for machine learning. The processor 110 may process computational processes such as the processing of input data for machine learning, the extraction of features for machine learning, and the calculation of errors based on backpropagation. The processor 110 for performing such data processing may include a central processing unit (CPU), a general purpose graphics processing unit (GPGPU), a tensor processing unit (TPU), an application specific integrated circuit (ASIC), or a field programmable gate array (FPGA). Since the types of processor 110 described above are only examples, the type of processor 110 may be configured in various manners within a range understandable to those skilled in the art based on the content of the present disclosure.

The memory 120 according to an embodiment of the present disclosure may be understood as a configuration unit including hardware and/or software for storing and managing data that is processed in the computing device 100. That is, the memory 120 may store any type of data generated or determined by the processor 110 and any type of data received by the network unit 130. For example, the memory 120 may include at least one type of storage medium of a flash memory type, hard disk type, multimedia card micro type, and card type memory, random access memory (RAM), static random access memory (SRAM), read-only memory (ROM), electrically erasable programmable read only memory (EEPROM), programmable read-only memory (PROM), magnetic memory, a magnetic disk, and an optical disk. Furthermore, the memory 120 may include a database system that controls and manages data in a predetermined system. Since the types of memory 120 described above are only examples, the type of memory 120 may be configured in various manners within a range understandable to those skilled in the art based on the content of the present disclosure.

The memory 120 may structure, organize, and manage data necessary for the processor 110 to perform computation, the combination of data, and program codes executable on the processor 110. For example, the memory 120 may store semiconductor data received through the network unit 130 to be described later. The memory 120 may store program code for causing a neural network model to receive semiconductor data and perform learning, program code for causing the neural network model to accept the semiconductor data and perform inference according to a purpose of use of the computing device 100, processing data generated as the program code is executed, and the like.

The network unit 130 according to an embodiment of the present disclosure may be understood as a configuration unit that transmits and receives data through any type of known wired/wireless communication system. For example, the network unit 130 may perform data transmission and reception using a wired/wireless communication system such as a local area network (LAN), a wideband code division multiple access (WCDMA) network, a long term evolution (LTE) network, the wireless broadband Internet (WiBro), a 5th generation mobile communication (5G) network, a ultra wide-band wireless communication network, a ZigBee network, a radio frequency (RF) communication network, a wireless LAN, a wireless fidelity network, a near field communication (NFC) network, or a Bluetooth network. Since the above-described communication systems are only examples, the wired/wireless communication system for the data transmission and reception of the network unit 130 may be applied in various manners other than the above-described examples.

The network unit 130 may receive data necessary for the processor 110 to perform an operation through wired/wireless communication with any system or any client or the like. In addition, the network unit 130 may transmit the generated data through the operation of the processor 110 through wired/wireless communication with any system, any client, or the like. For example, the network unit 130 may receive semiconductor design data through communication with a cloud server, a computing device, or the like that performs operations such as databases related to semiconductor design and processes, standardization of design data, or the like. The network unit 130 may transmit the output data of the neural network model, intermediate data derived in the operation process of the processor 110, processing data, and the like through communication with the database, the server, the computing device, or the like described above.

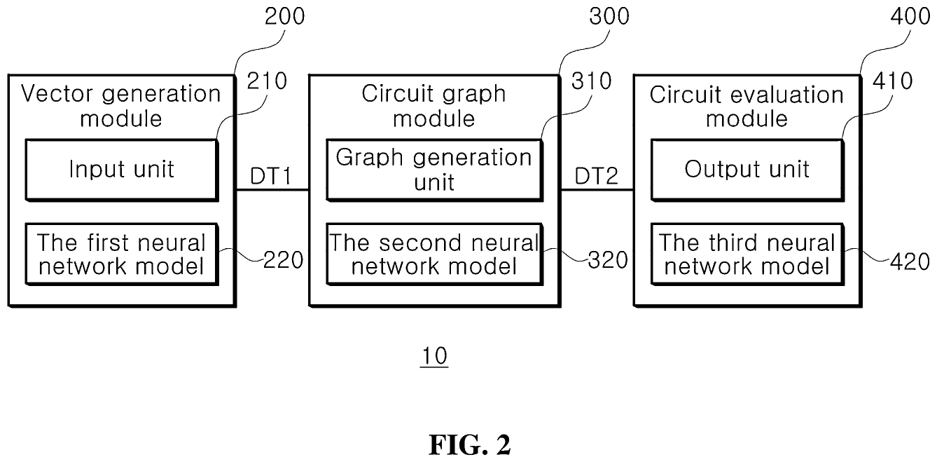

FIG. 2 is a block diagram illustrating a circuit evaluation apparatus according to an embodiment of the present disclosure.

Referring to FIG. 2, the circuit evaluation device 10 may include a vector generation module 200, a circuit graph module 300, and a circuit evaluation module 400. The vector generation module 200 may include a device including a transistor, a diode, or the like, an input unit 210 for receiving information of a characteristic of the device or a circuit to be evaluated, and a first neural network model 220 trained to generate a vector based on the device included in the circuit to be evaluated. For convenience of description, the input unit 210 is displayed in a form included in the vector generation module 200, and the input unit 210 receives various inputs such as devices, characteristics of the devices, information of the circuit to be evaluated, and data for training the first neural network model 220, but the data input method may be implemented in various forms.

For example, the first neural network model 220 may be a neural network model trained based on measurement data or electrical characteristics of a device including drain-source voltage, gate-source voltage, bulk-source voltage, drain current, or gate capacitance to generate a vector that well represents characteristics of a particular transistor. The first neural network model 220 may be any one of a convolutional neural network (CNN), a recurrent neural network (RNN), a Generative Adversarial Network (GAN), and a transformer, and types of neural network models are exemplarily listed for convenience of description, and are not limited thereto.

The device that is the input of the vector generation module 200 or the input of the first neural network model 220 may be various devices such as a MOSFET, a BJT, a diode, a resistor, a capacitance, a NAND gate, and the like. For example, the measurement data used in each device is as follows.
MOSFET: [Vds (Drain-Source Voltage), Vgs (Gate-Source Voltage), Vbs (Bulk-Source Voltage), Id (Drain Current), Cgg (Gate-Gate Capacitance), Cgb (Gate-Bulk Capacitance), . . . ]
BJT: [Vbe (Base-Emitter Voltage), Voe (Collector-Emitter Voltage), Ic (Collector Current), Ib (Base Current), . . . ]
Diode: [Vd (Diode Voltage), Id (Diode current), . . . ]
Resistance: [Vr (voltage over resistor), Ir]
Capacitance: [Vc, Qc, Ic, . . . ]
NAND Gate: [Vin1, Vin2, Vout]

The vector generation module 200 may use a neural network model trained separately according to the type of the device. For example, for MOSFETs, vectors can be generated using artificial neural network models learned based on Vds (Drain-Source Voltage), Vgs (Gate-Source voltage), Vbs (Bulk-Source voltage), Id (Drain Current), Cgg (Gate-Gate Capacitance), Cgb (Gate-Bulk Capacitance) and for BJTs, vectors generated using artificial neural networks models learned based on vbe (Base-Emitter Voltage), vce (Collector-Emitter voltage), Ic (Colleitor Current), and Ib (Base Current).

The vector generated in the vector generation module 200 may well include characteristics of a device, and may then be utilized to quickly predict performance of a circuit in which the device is included.

The circuit graph module 300 may include a graph generation unit 310 and a second neural network model 320. The graph generation unit 310 may generate a target circuit graph including a plurality of nodes and edges based on target circuit data including circuit information to be simulated or evaluated. The graph generation unit 310 may use device vectors generated through the first neural network model 220 for some devices, and map device information such as parameters explicitly known for the remaining devices into vectors of the same dimension as the device vectors generated by the first neural network models 220 for use.

Each of the nodes generated in the graph generation unit 310 corresponds to a device or a device vector included in the target circuit, and an edge may correspond to a connection relationship between the devices. The circuit graph module 300 may receive the first data DT1 including the device vectors generated by the vector generation module 200.

Since the second neural network model 320 generates a target circuit vector indicating circuit characteristics by using a graph, a graph neural network (GNN), a graph convolutional network (GCN), or a graph attention network (GAT) may be used, but the present invention is not limited thereto, and various neural network models may be used.

The circuit evaluation module 400 may include an output unit 410 and a third neural network model 420. The circuit evaluation module 400 may receive the second data DT2 including the target circuit vector generated by the circuit graph module 300. The circuit evaluation module 400 may predict various figure of merit (POM) such as gain, power, bandwidth, or delay of the circuit to be evaluated. The circuit evaluation module 400 may predict a state of various devices such as a voltage or a current applied to each device (or a node corresponding to the device) included in the circuit to be evaluated. The third neural network model 420 may be trained to predict various figure of merit (POM) such as gain (Gain), power (Power), bandwidth (Bandwidth), or delay of the circuit to be evaluated based on the target circuit vector generated by the second neural network model 320.

The third neural network model 420 may be trained to predict a voltage or a current applied to a specific device (or a corresponding node) of the evaluation target circuit based on the target circuit vector generated by the second neural network model 320 and the specific device vector of the evaluation target Circuit.

The circuit evaluation module 400 may predict a figure of merit (POM) or a state change of a specific device while changing a specific device vector included in a circuit to be evaluated.

When the type of the figure of merit (POM) of the circuit to be evaluated varies, the neural network model may be trained separately for each circuit.

The output unit 410 may include a display for displaying the generated circuit evaluation data, a communication module for transmitting the circuit evaluation data, and the like. The output unit 410 may include a user interface (UI) for displaying and visualizing the generated circuit evaluation data.

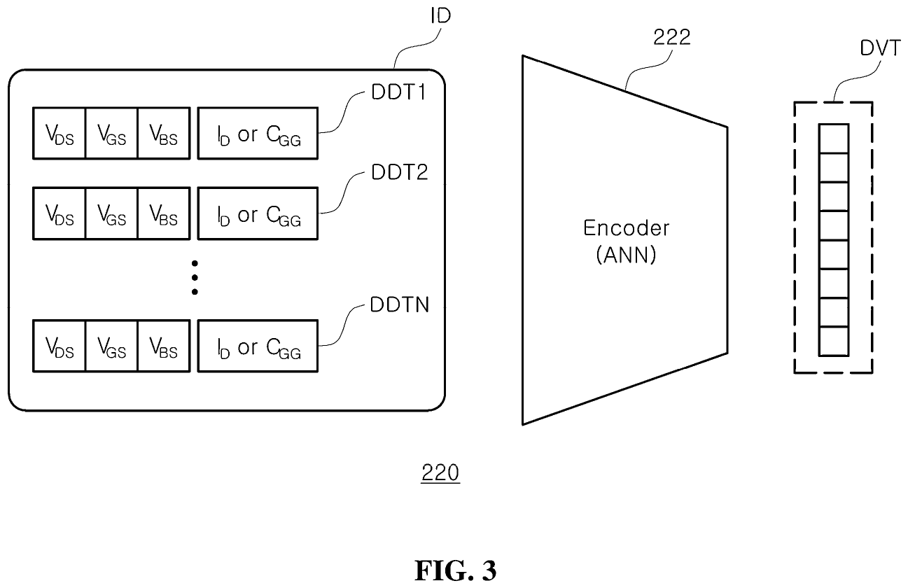

FIG. 3 is a diagram illustrating a first neural network model for generating a device vector according to an embodiment of the present disclosure.

Referring to FIG. 3, the first neural network model 220 may be trained to generate the device vector DVT based on the measurement data ID including the drain-source voltage, the gate-source voltage, a bulk-source voltage, drain current, or gate capacitance of the transistor included in the circuit to be evaluated.

The first neural network model 220 may include any one of a convolutional neural network (CNN), a recurrent neural network (RNN), a Generative Adversarial Network (GAN), and a transformer, and types of neural network models are exemplarily listed for convenience of description, and are not limited thereto. The structure of the first neural network model 220 may be a multi-layer perceptron (MLP) including an aggregation/pooling layer because any number of input vectors may be received, and may further include a self-attention structure. For example, the first neural network model 220 may linearly transform each input vector, transform the input vector into a context-aware representation using self-attention, and max pool the input vector into one fixed vector.

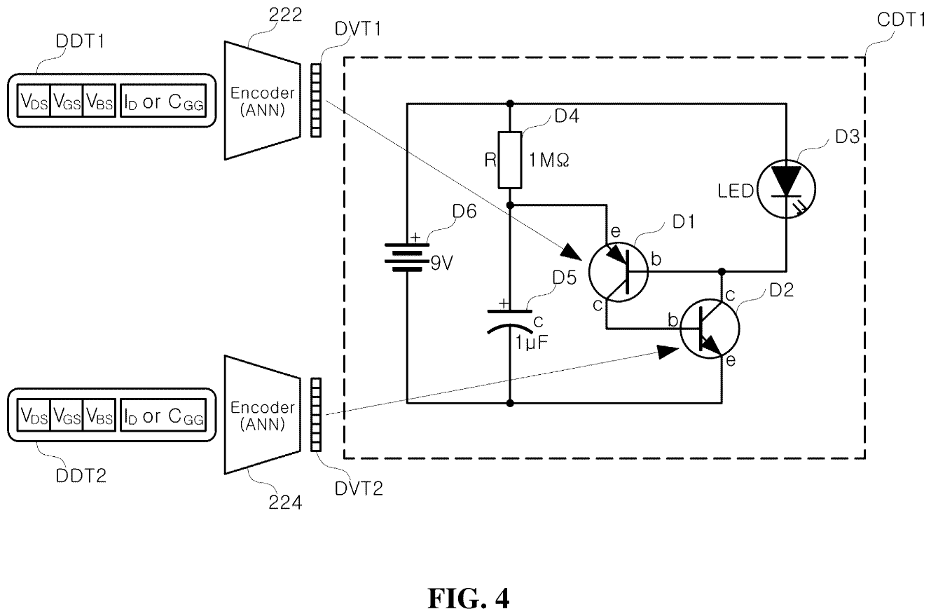

FIG. 4 is a diagram illustrating a device vector corresponding to a device of a circuit to be evaluated.

Referring to FIG. 4, the evaluation target circuit CDT1 may include a first device D1 and a second device D2. The first device D1 may be a PNP transistor, and the second device D2 may be an NPN transistor. In addition to the transistor, the evaluation target circuit CDT1 may include an LED third device D3, a resistor fourth device D4, a capacitor fifth device D5, and a power supply sixth device D6.

The artificial neural network model 222 for converting the first device D1, which is a PNP transistor, into a vector and the artificial neural network model 224 for converting into a vector of the second device D2, which is an NPN transistor, may be learned as separate artificial neural network models. The artificial neural network model can be learned separately for various devices such as MOSFETs, BJTs, diodes, resistors, capacitances, and NAND gates, and measurement data used for each device can be learned differently.

For example, for MOSFETs, vectors can be generated using artificial neural network models learned based on Vds (Drain-Source Voltage), Vgs (Gate-Source voltage), Vbs (Bulk-Source voltage), Id (Drain Current), Cgg (Gate-Gate Capacitance), Cgb (Gate-Bulk Capacitance) and for BJTs, vectors generated using artificial neural networks models learned based on vbe (Base-Emitter Voltage), vce (Collector-Emitter voltage), Ic (Colleitor Current), and Ib (Base Current).

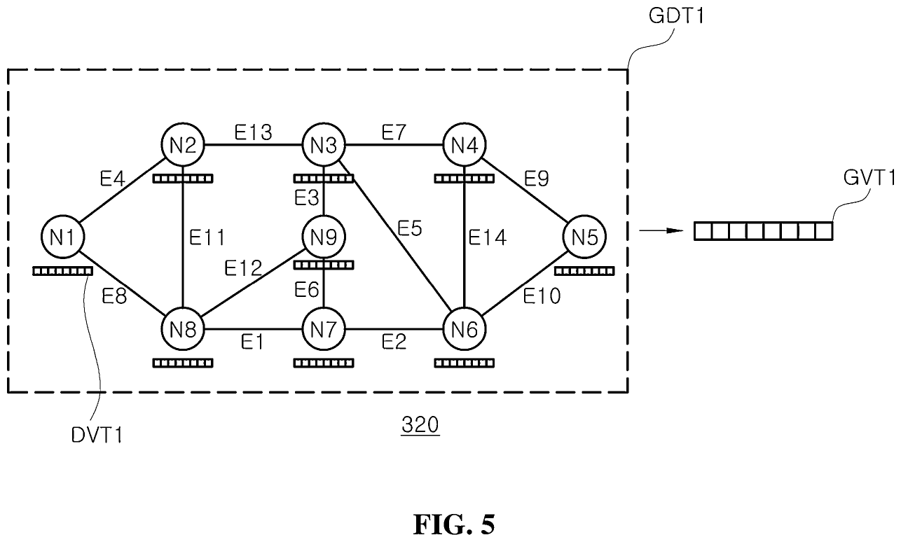

FIG. 5 is a diagram illustrating a second neural network model for generating a vector representing a circuit characteristic according to an embodiment of the present disclosure.

Referring to FIGS. 2 to 5, the second neural network model 320 may generate the target circuit vector GVT1 by inputting the target circuit graph GDT1. For example, the first node N1 of the target circuit graph GDT1 may include the first device vector DVT1 generated by the first neural network model 220. The node of the target circuit graph GDT1 may include device vector information corresponding to devices constituting the circuit.

Since the second neural network model 320 generates a target circuit vector indicating circuit characteristics by using a graph, a graph neural network (GNN), a graph convolutional network (GCN), or a graph attention network (GAT) may be used, but the present invention is not limited thereto, and various neural network models may be used.

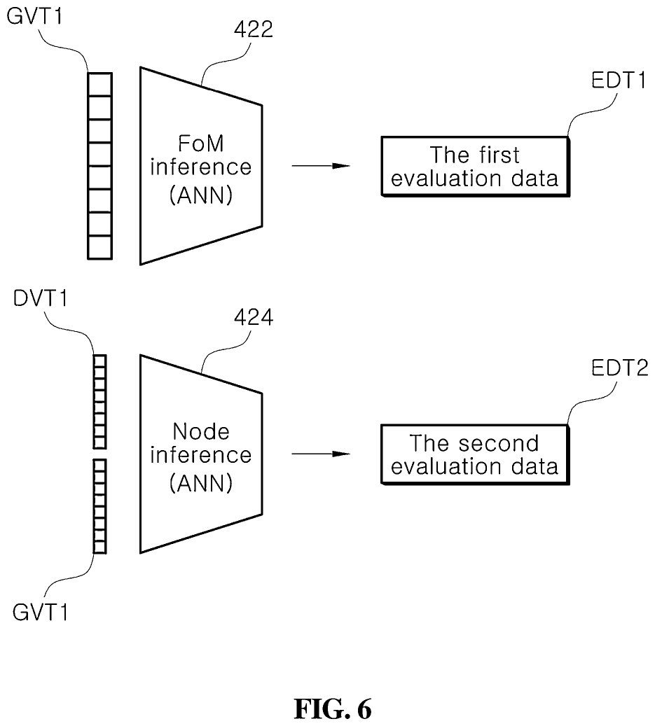

FIG. 6 is a diagram illustrating a third neural network model for generating circuit evaluation data according to an embodiment of the present disclosure.

Referring to FIGS. 5 and 6, the circuit evaluation module may include a third neural network model 422, 424 that generates circuit evaluation data. The third neural network model 422 may predict the first evaluation data EPT1 by inputting the target circuit vector GVT1 generated by the second neural network model 320.

The first evaluation data ETT1 may include various figure of merit (POM) such as gain, power, bandwidth, or delay of the circuit to be evaluated.

The circuit evaluation module may predict a state of various devices such as a voltage or a current applied to each device (or a node corresponding to the device) included in the circuit to be evaluated. The third neural network model 424 may generate second evaluation data ETT2 including a voltage or a current applied to a specific device (or a corresponding node, N1) of the circuit to be evaluated based on the target circuit vector GVT1 generated by the second neural network model 320 and the specific device vector DVT1 of the circuit to be evaluated. When the type of the figure of merit (POM) of the circuit to be evaluated varies, the neural network model may be trained separately for each circuit.

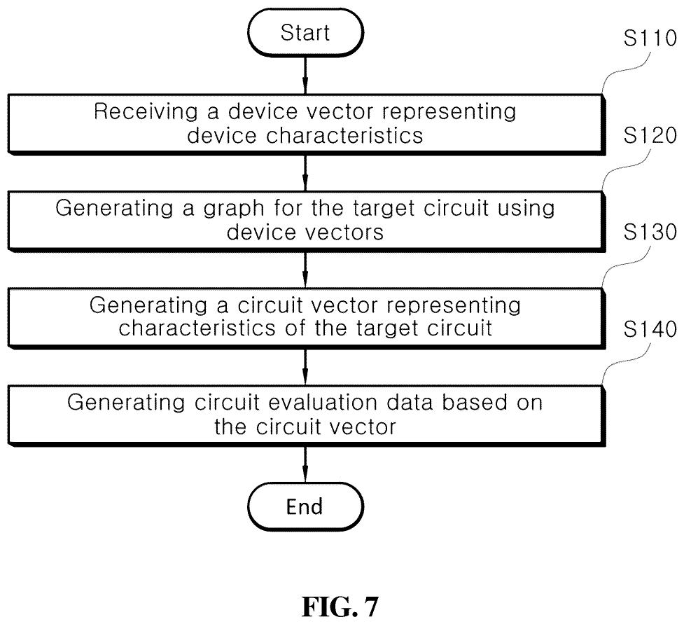

FIG. 7 is a flowchart illustrating a circuit evaluation method according to an embodiment of the present disclosure.

Referring to FIG. 7, the circuit evaluation device may receive a device vector representing a device characteristic (S110). Although FIG. 2 illustrates that the circuit evaluation device 10 generates a graph by using the vector (or the device vector) generated by the vector generation module 200, the first neural network model that generates the device vector based on the device and the characteristic information of the device used in the circuit design may be trained on a computing device separate from the circuit evaluation device and generate the device vector. The circuit evaluation device may receive, from an external computing device, device vectors corresponding to devices included in the simulation or evaluation target circuit. The circuit evaluation device may include a pre-trained first neural network model, and a device vector corresponding to devices included in the circuit to be evaluated may be generated by a vector generation module included in the circuit evaluation device.

The circuit evaluation device may generate a graph for the target circuit by using the device vectors (S120). The circuit evaluation device may generate a target circuit graph including a plurality of nodes and edges based on the target circuit data including the circuit information to be evaluated. Each node included in the generated target circuit graph corresponds to a device or a device vector included in the target circuit, and an edge may correspond to a connection relationship between the devices.

The circuit evaluation device may generate a circuit vector representing the target circuit characteristic (S130). The circuit evaluation device may generate the target circuit vector through the trained second neural network model based on the generated target circuit graph. Since the second neural network model generates a target circuit vector indicating circuit characteristics by using a graph, a graph neural network (GNN), a graph convolutional network (GCN), or a graph attention network (GAT) may be used.

The circuit evaluation device may generate circuit evaluation data based on the target circuit vector (S140). The circuit evaluation device may predict various figure of merit (POM) such as gain, power, bandwidth, or delay of the circuit to be evaluated. The circuit evaluation device may predict a state of various devices such as a voltage or a current applied to each device (or a node corresponding to the device) included in the evaluation target circuit. The circuit evaluation device may predict various figure of merit (POM) such as gain, power, bandwidth, or delay of the circuit to be evaluated by using the third neural network model 420 as an input of the target circuit vector.

The circuit evaluation device may predict a voltage or a current applied to a specific device (or a corresponding node) of the circuit to be evaluated based on the target circuit vector and the specific device vector in the circuit to be evaluation.

The various embodiments of the present disclosure described above may be combined with further embodiments and may vary in scope as would be understood by one of ordinary skill in the art in light of the above detailed description. It should be understood that the embodiments of the present disclosure are illustrative in all respects and not restrictive. For example, each component described as being unitary may be implemented in a distributed manner, and likewise, components described as being distributed may also be implemented in a combined manner. Therefore, all changes or modifications derived from the meaning, scope and equivalent concepts of the claims of the present disclosure are to be construed as being included in the scope of the present disclosure.

The various embodiments of the present disclosure described above may be combined with one or more additional embodiments, and may be changed within the range understandable to those skilled in the art in light of the above detailed description. The embodiments of the present disclosure should be understood as illustrative but not restrictive in all respects. For example, individual components described as unitary may be implemented in a distributed manner, and similarly, the components described as distributed may also be implemented in a combined form. Accordingly, all changes or modifications derived from the meanings and scopes of the claims of the present disclosure and their equivalents should be construed as being included in the scope of the present disclosure.

1. A method of evaluating circuit, the method being performed by a computing device that includes at least one processor, the method comprising:
generating a target circuit graph comprising a plurality of nodes and edges based on target circuit data;
generating a target circuit vector based on the target circuit graph; and
generating circuit evaluation data based on the target circuit vector.

2. The method of claim 1,
wherein the target circuit data comprises a device vector of a predetermined dimension generated on the basis of electrical characteristics or measurement data of a device.

3. The method of claim 2,
the device vector is generated by a pre-trained first neural network model, and
wherein the first neural network model includes any one of a convolutional neural network (CNN), a recurrent neural network (RNN), a Generative Adversarial Network (GAN), and a transformer.

4. The method of claim 2,
wherein the device comprises a transistor,
wherein the electrical characteristics or measurement data of the device comprise a drain-source voltage, a gate-source voltage, a bulk-source voltage, a drain current or a gate capacitance.

5. The method of claim 1, further comprising:
generating the target circuit vector by using a second neural network model including a graph neural network (GNN), a graph convolutional network (GCN), or a graph attention network (GAT).

6. The method of claim 1,
wherein the circuit evaluation data includes a figure of merit (POM) corresponding to the target circuit data, and
wherein the figure of merit comprises one or more of Gain, Power, Bandwidth or Delay.

7. The method of claim 1,
Wherein generating the circuit evaluation data further comprises predicting a voltage or a current applied to any one of the plurality of nodes based on the target circuit vector and a device vector corresponding to the node.

8. An apparatus for evaluating circuit using an artificial neural network, comprising:
a circuit graph module, configured to generate a target circuit vector based on target circuit data;
wherein the target circuit data includes one or more device information and connection relationship information between devices, and
wherein the circuit graph module includes a graph generation unit that generates a target circuit graph including a plurality of nodes corresponding to the device information and edges corresponding to connection relationship information between devices, and a second neural network model trained to generate a target circuit vector based on the target circuit graph.

9. The apparatus for evaluating circuit of claim 8, further comprising:
a vector generation module, configured to generate a device vector of a preset dimension generated based on electrical characteristics of a device or measurement data,
wherein the target circuit data includes the device vector.

10. The apparatus for evaluating circuit of claim 9,
wherein the vector generation module includes a first neural network model trained to generate the device vector based on electrical characteristics of the device or measurement data, and
wherein the first neural network model includes any one of a convolutional neural network (CNN), a recurrent neural network (RNN), a Generative Adversarial Network (GAN), and a transformer.

11. The apparatus for evaluating circuit of claim 10, wherein the first neural network model is trained to generate the device vector based on a drain-source voltage, a gate-source voltage, a bulk-source voltage, a drain current, a gate capacitance, an I-V characteristic, or a C-V characteristic.

12. The apparatus for evaluating circuit of claim 8, wherein the second neural network model is any one of a Graph Neural Network (GNN), a Graph Convolution Network (GCN), or a Graph Attention Network (GAT).

13. The apparatus for evaluating circuit of claim 8, further comprising:
a circuit evaluation module configured to predict performance corresponding to the target circuit data;
wherein the performance is a figure of merit (POM) including one or more of gain, power, bandwidth, or delay.

14. The apparatus for evaluating circuit of claim 13, wherein the circuit evaluation module includes a third neural network model trained to predict the performance based on the target circuit vector.

15. The apparatus for evaluating circuit of claim 10, further comprising:
a circuit evaluation module configured to predict a state of any one of devices included in the target circuit data, wherein the circuit evaluation module includes a third neural network model trained to predict a voltage or a current applied to a device corresponding to the device vector based on the target circuit vector and the device vector.

16. A computing device for evaluating circuit based on a trained neural network model, the computing device comprising:
a processor including at least one core;
a memory comprising program codes that are executable on the processor, and
a network unit configured to acquire data;
wherein the processor:
generates a target circuit graph based on target circuit data, generates a target circuit vector based on the generated target circuit graph, and generates circuit evaluation data based on the target circuit vector,
wherein the target circuit data includes one or more device information and connection relationship information between devices, and
wherein the target circuit graph includes a plurality of nodes corresponding to the device information and edges corresponding to connection relationship information between devices, and
wherein the target circuit vector is generated by using a neural network model of any one of a Graph Neural Network (GNN), a Graph Convolution Network (GCN), and a Graph Attention Network (GAT) as an input of the target circuit graph.

17. The computing device of claim 16,
Wherein a node included in the target circuit graph includes a device vector of a preset dimension generated by using a neural network model based on electrical characteristics or measurement data of a device corresponding to the node.
